(19) United States
(12) Patent Application Publication
(10) Pub. No.: US 2003/0034849 A1
(43) Pub. Date: Feb. 20, 2003

(54) Ring oscillator stage

(76) Inventor: Mihai Adrian Tiberiu Sanduleanu, Eindhoven (NL)

Correspondence Address: Michael E. Marion, c/o U.S. PHILIPS CORPORATION, Intellectual Property Department, 580 White Plains Road, Tarrytown, NY, 10591, US

(21) Appl. No.: 10/218,228

(22) Filed: Aug. 13, 2002

(30) Foreign Application Priority Data
Aug. 16, 2001 (EP) 01203124.1

(51) Int. Cl. H03B 1/00

(52) U.S. Cl. 331/58

(57) ABSTRACT

The present invention relates to a ring oscillator stage, comprising delay means (32) having an input and an output, and further comprising adjustable negative resistor means (−RTUNE) coupled to the output of said delay means (32).

The present invention relates to a ring oscillator stage comprising delay means having an input and an output.

Ring oscillators are widely known in the field of integrated circuit manufacture and usually comprise simple inverting logic circuits as stages. The current output of each stage takes a certain time to charge or discharge an input capacitance of the following stage to a threshold voltage. The stages are connected in series to form a cascade loop, so that at a certain frequency a 180° phase shift is imparted to signals passing around the loop. Provided the loop gain is large enough, the signals soon become non-linear resulting in square-wave oscillations which can be used for a variety of purposes, in particular for digital signal processing.

In metal-oxide-semiconductor (MOS) integrated circuits, ring oscillators are commonly used to drive charge pump circuits. In particular, ring oscillators are provided in BiCMOS or Bipolar and also in pure CMOS circuits. A preferred application of ring oscillators is the provision in data and clock recovery circuits or in PLL circuits.

However, ring oscillators suffer from uncertainty in the frequency of oscillation, due to variations resulting from both the manufacturing process and operating conditions such as supply voltage and temperature. This problem results from the fact that the frequency is determined only by parameters inherent to the inverter stages and the devices used to construct them. Further, the frequency can be reduced by increasing the number of stages to a certain extent only, since harmonics occur at higher frequencies, and in practice this limits the number of stages.

Therefore, the EP 0 322 047 A2 proposes the provision of a separate, active output circuit in at least one stage which active circuit regulates the output currents so as to regulate the frequency of oscillation. By providing such a separate, active output circuit in the stage, the time delay caused by the stage can be made independent of ill-defined and/or variable characteristics of the devices and circuits used. Further provided is a reference circuit which can be used by more than one stage.

U.S. Pat. No. 5,691,669 A discloses dual adjust current-controlled phase locked loop which is provided for a allowing multiple-gain frequency acquisition of a signal. The dual adjust current-controlled phase locked loop includes a phase detector responsive to a reference signal and a synthesized signal for producing a phase error signal, a controller responsive to the phase error signal for generating coarse and fine adjust control signals, and a dual adjust current-controlled oscillator responsive to the coarse and fine adjust control signals for adjusting the oscillating frequency of the synthesized signal. The dual adjust current-controlled oscillator includes a differential current-controlled ring oscillator comprising a series of delay elements. Each delay element includes a high gain circuit responsive to the coarse adjust control signal and a low gain circuit responsive to the fine adjust control signal.

In order to achieve a high oscillator frequency in the GHz range, an obvious choice would be to limit the number of stages to two. The oscillator frequency can be varied by changing the delay per stage and if one can ensure a fine and a coarse tuning mechanism, then the oscillator will have two tuning ports. In optical networking application for applications above 10 GB/s low phase noise is essential to recover the clock in a Data and Clock Recovery circuit (DCR) with the additional requirement that the oscillator should provide an oscillation frequency stable with temperature and process variations. For some applications with more than one Data rate, a large tuning range oscillator is required. The linearity of the oscillator is also important for the reason of keeping the loop bandwidth of the PLL constant for different tuning situations.

It is an object of the present invention to provide a ring oscillator stage wherein the frequency of oscillation can be controlled in a more precise and convenient way.

In order to achieve the above object, in accordance with the present invention, there is provided a ring oscillator stage comprising delay means having an input and an output, further characterised by adjustable negative resistor means coupled to said delay means, in particular to the output of said delay means.

The adjustable negative resistor means has the function of fine tuning means. Namely, by adjusting the negative resistor value of the negative resistor means the current through the negative resistor means are changed resulting in tuning the frequency of the ring oscillator. It has been found that such construction allows fine tuning of the oscillating frequency.

Since tuning and in particular fine tuning can also be achieved by changing the current through the delay means, current adjusting means for adjusting the current through the delay means can be provided in addition to the adjustable negative resistor means.

Further provided can be an adjustable load means which is connected to the output of the delay means. Usually, the adjustable load means comprise adjustable resistors. The main time constant in the ring oscillator stage results from the combination of the adjustable load means being positive resistor means and the adjustable negative resistor means and a parasitic capacitance ‘seen’ in parallel to the load means. Changing the value of the adjustable load means results in a further tuning which has the effect of coarse tuning in addition to the fine tuning achieved by the adjustable negative resistor means. By coarse tuning, the frequency varies non-linearly with the stimulus, but over a large tuning range, in particular of more than one octave. So, in this embodiment provided is a two-tuning mechanism system comprising of a fine tuning mechanism and a coarse tuning mechanism, which has the advantage of a better immunity against phase noise coming from the power supply and the substrate.

In order to provide a level shifting operation and to minimize the loading effect of the next oscillator stage, preferably an output buffer means can be connected to the output of the delay means.

Usually, the output buffer means includes a transistor, i.e. at least one transistor is an element of the output buffer means. In this case, it has been found by the present invention that such a transistor can also be provided to be an element of the adjustable negative resistor. The common use of such transistor by the output buffer means on the one hand and by the adjustable negative resistor on the other hand results in a more simple construction.

For a better control of the amplitude of the ring oscillator stage, a replica biasing means can be provided, too.

Finally, it is hinted that the invention can be implemented not only in a single-ended ring oscillator stage where the delay means usually consists of an inverter means, but also in a differential ring oscillator stage where the delay means can consist of a delay means or a gain amplifier means.

The above and other objects and features of the present invention will become clear from the following description taken in conjunction with the preferred embodiment with reference to the accompanying drawings in which:

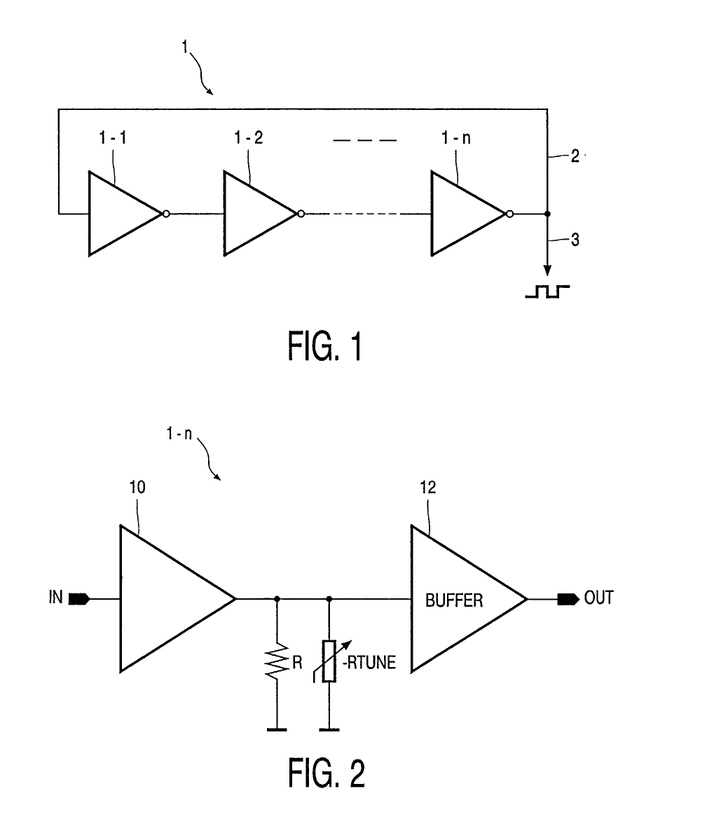

FIG. 1 is a schematic block diagram of a single-ended ring oscillator;

FIG. 2 is a schematic block diagram of a preferred embodiment of a single-ended ring oscillator stage according to the present invention;

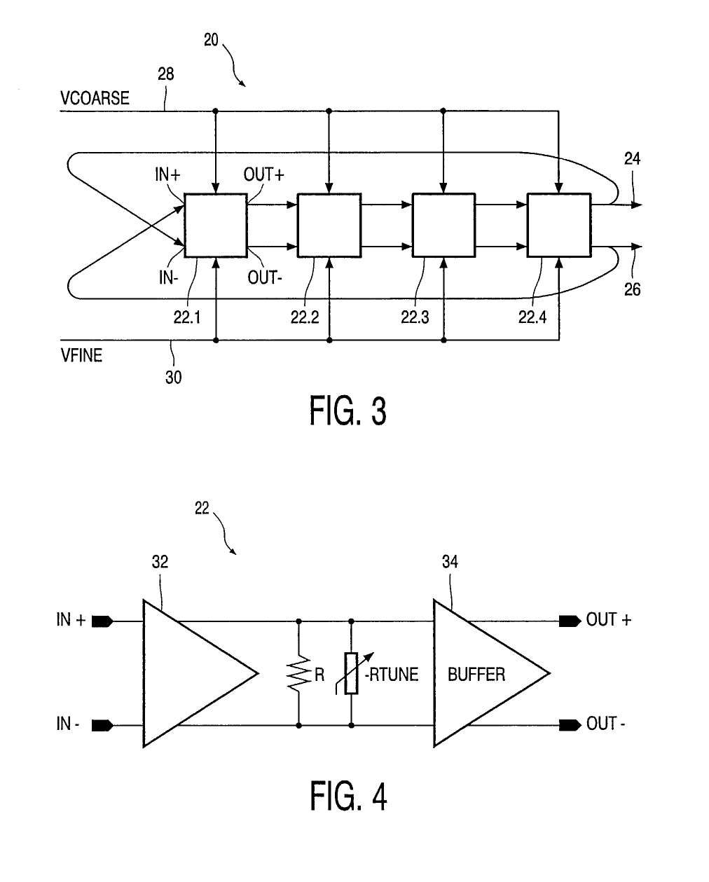

FIG. 3 is a schematic block diagram of a differential ring oscillator;

FIG. 4 is a schematic block diagram of a preferred embodiment of a differential ring oscillator stage according to the present invention;

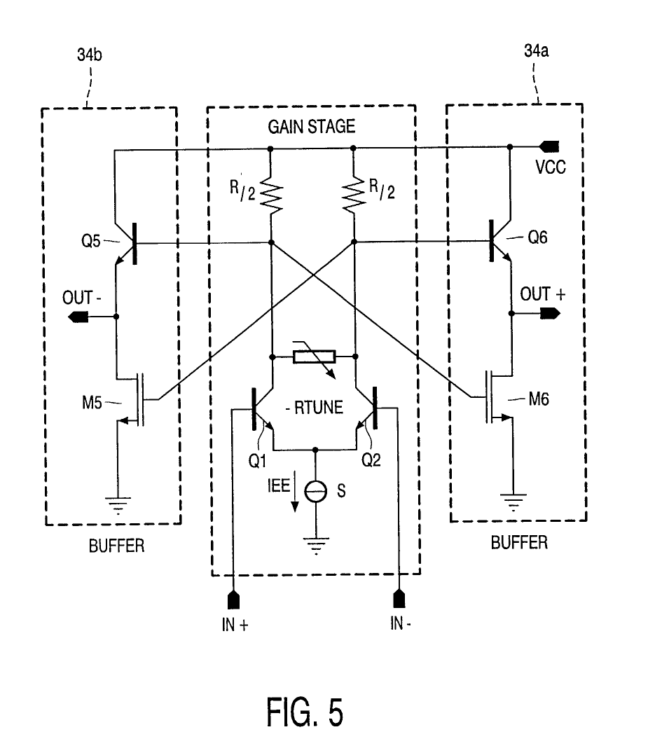

FIG. 5 is a schematic circuit diagram of the differential ring oscillator stage of FIG. 4;

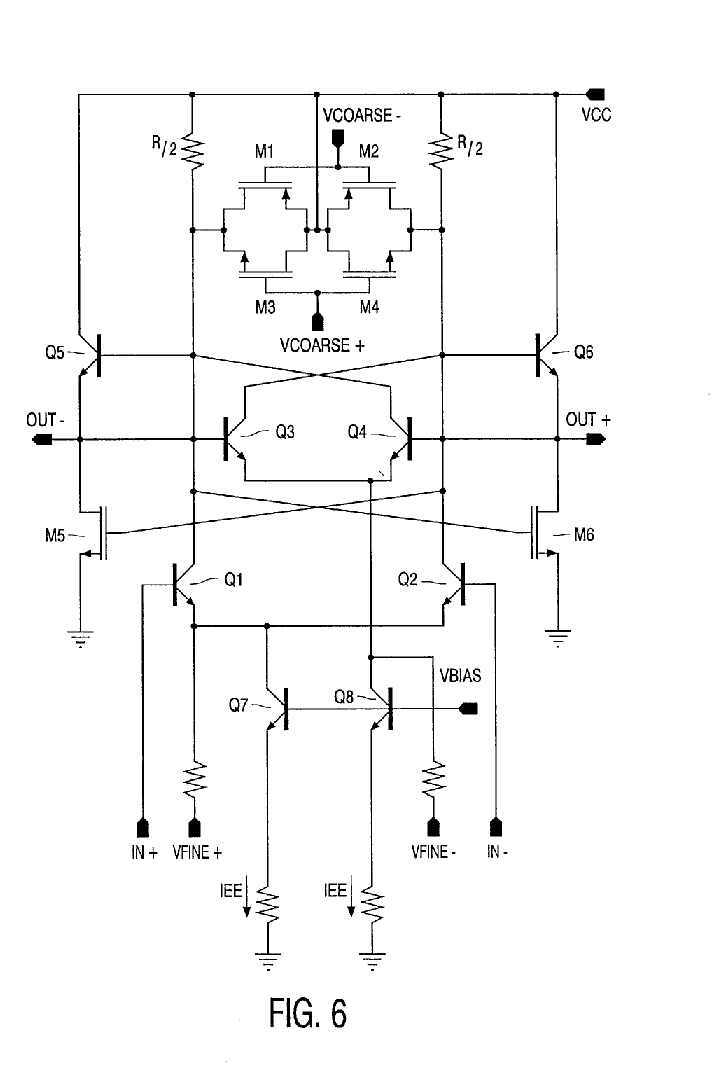

FIG. 6 a more detailed circuit diagram of the differential ring oscillator stage of FIG. 5;

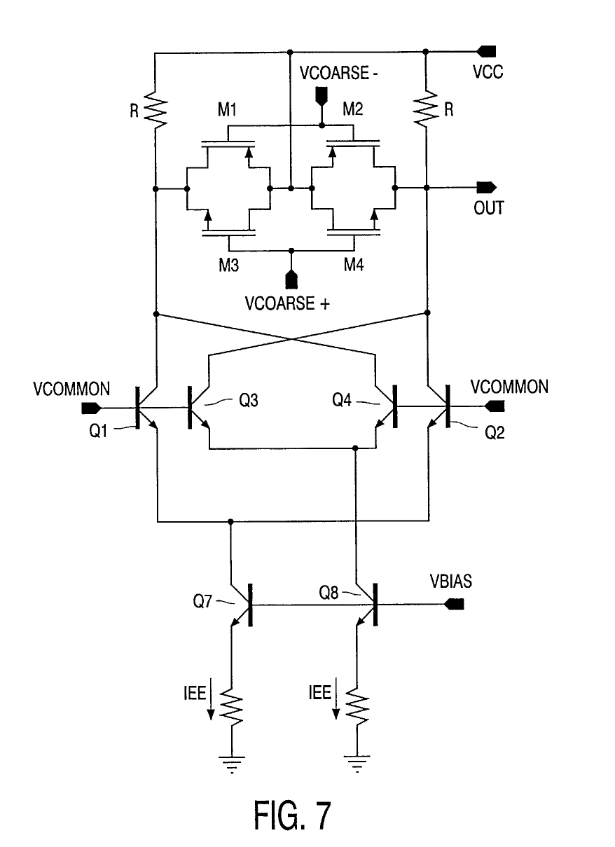

FIG. 7 a replica bias circuit for use in a ring oscillator stage;

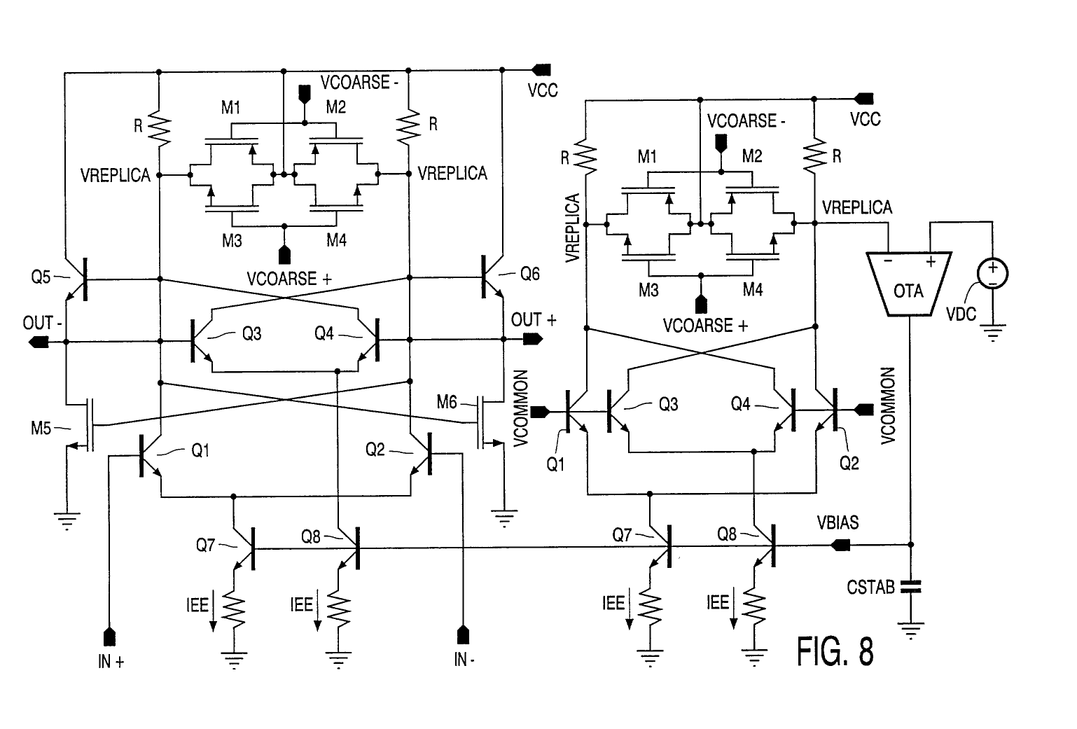

FIG. 8 a complete circuit including the differential ring oscillator stage of FIG. 6 and the replica bias circuit of FIG. 7;

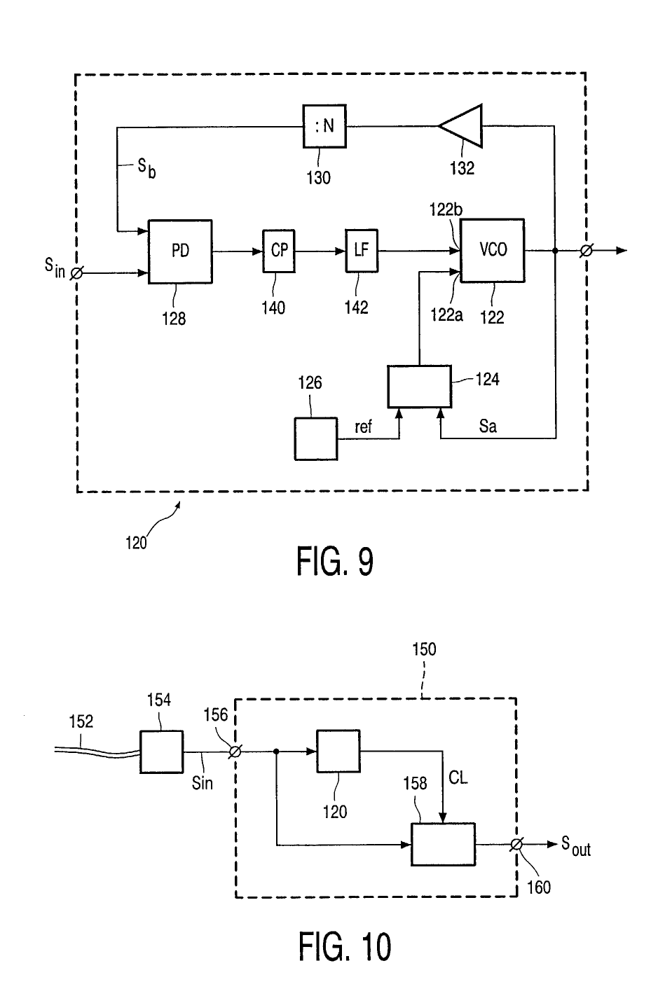

FIG. 9 a preferred embodiment of a clock recovery circuit including an oscillator;

FIG. 10 a preferred embodiment of a receiver for a fiber-optic channel including the clock recovery circuit of FIG. 9; and

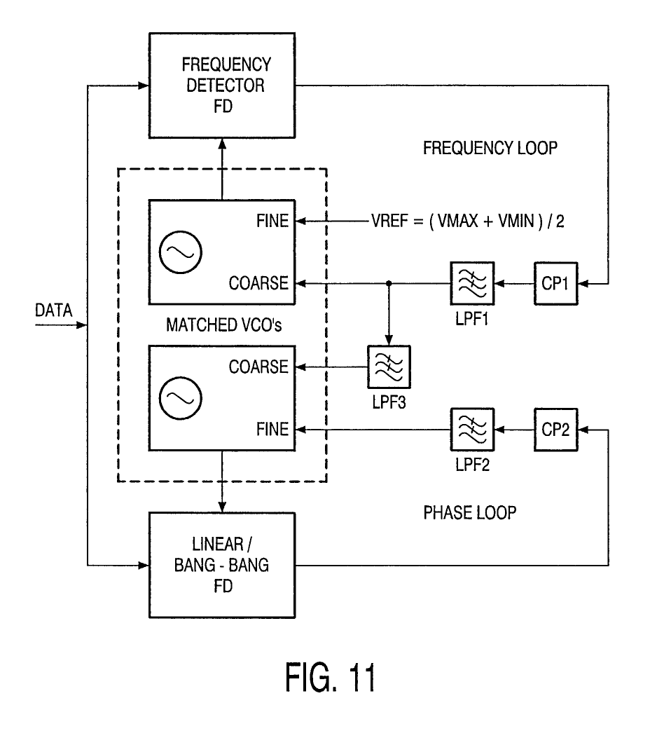

FIG. 11 a further preferred embodiment of a data and clock recovery unit including two oscillators.

FIG. 1 is a schematic block diagram of a single-ended ring oscillator 1. The ring oscillator 1 comprises a number of n cells or stages 1-1 to 1-n. Each stage comprises an input, an inverting delay element and an output, and the stages are connected in series. The output of the nth stage 1-n is connected via a feedback path 2 to the input of the first inverter 1-1 to close the loop. The output of the nth stage 1-n also forms an output 3 of the oscillator 1. The number n of stages is an odd number of 3 or more. The circuit acts as a phase-shift oscillator, whose natural frequency of oscillation f is that for which a phase lag of 180° occurs over the chain of the stages 1-1 to 1-n. In practice, the very high gain of logic circuits ensures that the circuit becomes highly non-linear and generates a square wave of frequency f at the output 3. The period 1/f of the square wave is simply twice the propergation delay through the n stages which have the effect of delay means either. A similar square wave is present at the output of each stage 1-1 to 1-n, with a phase shift of 180/n degrees each time (assuming that all inverters 1-1 to 1-n are identical). Consequently, the oscillator output could be taken from the output of any of the stages.

FIG. 2 shows a schematic block diagram of a single-ended ring oscillator stage in accordance with a preferred embodiment of the present invention. This stage comprises a delay element 10 which delays an input signal inputted into the input terminal IN+. The ring oscillator stage further comprises a load consisting of a positive resistor R, and a negative resistor −RTUNE. The positive and negative resistors are connected to the output of the delay element 10. In order to provide a level shifting operation and to minimize the loading effect of the next stage, an output buffer 12 is connected to the output of the delay element 10, wherein the output of the output buffer 12 defines the output terminal OUT+ of the ring oscillator stage.

The main time constant in the oscillator results from the parallel combination of the positive and negative resistors and the parasitic capacitance ‘seen’ in parallel by the load. By tuning the negative resistance −RTUNE, the delay per oscillator stage is tuned and therefore the oscillator frequency is changed. However, when tuning also the positive resistance R, then a two-tuning mechanism is provided.

The oscillator consisting of the oscillator stages as described here can be preferably realised in SiGe technology for high frequency operation, and it can be tuned in the range of 4 to 14 GHz which is needed in a 10 GB/s system in order to accommodate also the forward error correction (FEC) data rates.

FIG. 3 shows a schematic block diagram of a differential ring oscillator 20 which comprises a series of differential ring oscillator cells or stages 22.1 to 22.4 connected in series. As shown in FIG. 3, each stage comprises a first input IN+, a complemented or inverse second input IN−, a first output OUT+ and a complemented or inverse second output OUT−, wherein the inverse second input IN− is substantially the complement of the first input IN+ and the inverse second output OUT− is substantially the complement of the first output OUT+. As further shown in FIG. 3, the first output of the last stage 22.4 in the series of stages is connected to the inverse second input of the first 22.4, and the inverse second output of the last stage 22.1 is connected to the first input of the first stage 22.1, so as to form a ring. Moreover, the first output of the last stage 22.4 is connected to a first output terminal 24 of the oscillator 20, and the inverse second output of the last stage 22.4 is connected to a second output terminal 26 of the oscillator 20. So, at the first output terminal 24 of the oscillator 20 a first output signal is outputted, and at the second output terminal 26 of the oscillator 20 an inverse second output signal is outputted, wherein the inverse second output signal is substantially a complement of the first output signal.

In the embodiment shown in FIG. 3, the number of stages used is four. Since this is an even number and the inverse second output OUT− of each stage 22.1 to 22.4 of this embodiment generates an output signal having a phase shift of 180° with regard to the output signal outputted at the first output OUT+, the respective first and second output signals from the last stage 22.4 are used as the inverse second input signal and first input signal of the first stage 22.1, respectively, as already mentioned above. Because of the differential nature of each stage, any number of stages may be used to provide the ring oscillator. In contrast thereto, if an odd number of differential stages is used, the respective first and second output signals from the last stage in the series of stages are used as the respective first and second input signals of the first stage.

As also shown in FIG. 3, a coarse tuning control input 28 is provided for inputting a coarse tuning signal “VCOARSE”, and a fine tuning control input 30 is provided for inputting a fine tuning signal “VFINE”. By changing the coarse tuning signal “VCOAR-SE”, the frequency of the oscillator 20 is varied over a large tuning range, wherein the change of the fine tuning signal “VFINE” additionally allows the fine tuning of the frequency of the oscillator 20.

Usually, a minimal ring oscillator of the kind as shown in FIG. 3 consists of two stages which provide a delay t_{D} at the oscillation frequency. In order to satisfy the phase oscillation condition around the loop, it can be shown that the frequency of operation is:

$${f}_{0} = \frac{1}{{2}_{{t}_{D}}} . \qquad ( 1 )$$

It should be noted here that in the theoretical case the implementation of the inverting stages provides a 180° phase shift on the loop. However, there is always some phase shift due to parasitics which must be compensated for. Such compensation can be provided e.g. by using the delay on the transmission line.

FIG. 4 shows a schematic block diagram of a differential ring oscillator stage in accordance with a preferred embodiment of the present invention. A comparison between FIG. 2 and FIG. 4 shows that the elements of the differential ring oscillator stage of FIG. 4 correspond to those of the single-ended ring oscillator stage of FIG. 2, but have a differential construction or arrangement. So, the differential ring oscillator stage 22 shown in FIG. 4 comprises a differential delay element 32 and a differential output buffer 34. Further provided are an adjustable load consisting of an adjustable positive resistor R, and an adjustable negative resistor −RTUNE. The positive and negative resistors are coupled in parallel between a first junction connecting a first output of the differential delay element 32 and the corresponding input of the differential output buffer 34 and a second junction connecting the inverse output of the differential delay element 32 and the inverse input of the differential output buffer 34. The differential delay element 32 can consist of a differential inverter and/or a differential gain amplifier. The remaining aspects of the construction and the function of the differential ring oscillator stage 22 of FIG. 4 are the same as those of the single-ended ring oscillator stage of FIG. 2 so that with respect thereto reference is made to the above description of FIG. 2.

FIG. 5 shows the implementation of a gain stage which is defined by the delay element 32, the positive resistor R and the negative resistor −RTUNE of FIG. 4, and of the differential output buffer 34 consisting of a first output buffer 34a and an inverse output buffer 34b. The gain stage comprises a differential pair of positive resistors R/2 and the negative resistor −RTUNE followed by an emitter follower Q1 and Q2 with a MOS controlled current source S, wherein the delay element 32 of FIG. 4 is mainly defined by the transistors Q1 and Q2 and the current source S. MOS transistors M5 and M6 in the output buffers 34a, 34b provide a feed-forward control at the first output OUT+ and the inverse second output OUT−. Due to this configuration, the gain of the output buffer 34 is slightly higher than 1 dB, but the main advantage consists in the fact that the output buffer 34 is able to deliver more current to a capacitive load such that slewing effects at the outputs OUT+ and OUT− can be reduced. In a normal emitter follower, the constant current source in the emitter determines unequal rise and fall times. In an oscillator, this translates in non-symmetrical waves at the output which can worsen the phase noise. Since this oscillator provides sinusoidal, symmetrical waveforms at the output, the 1/f noise corner in the phase-noise spectrum is pushed towards the carrier minimizing the close-in phase noise of the oscillator. Also the noise coming from the up-conversion mechanisms is reduced.

On the other hand, when providing large amplitudes of oscillation, a normal emitter follower buffer can cause distortion when the output current source enters saturation. The MOS transistor has the advantage that going from saturation into linear region, the output resistance changes gradually without distorting the output waveform.

The implementation of the negative resistor −RTUNE is shown in FIG. 6. The current source S of FIG. 5 mainly comprises transistors Q7 and Q8. Transistors Q3 and Q4 work as a latch and in order to minimize the capacitive loading their base is connected to the outputs OUT− and OUT+. The coarse control comprising coarse tuning ports VCOARSE+ and VCOARSE− (corresponding to the coarse tuning control input 28 of FIG. 3) has been implemented differentially using a parallel connection of a NMOS and PMOS transistor M1, M3 and M2, M4, respectively. The netto load of the gain stage consists of a fixed resistor R in parallel with a differentially tunable MOS resistor and the differentially tunable negative resistance realized with the latch Q3-Q4. The fine tuning is realized by using a differential voltage at fine tuning ports VFINE+ and VFNE− (corresponding to the fine tuning control input 30 of FIG. 3) converted into a differential current by the series resistors connected in the emitters of Q1, Q2 and Q3, Q4 respectively. When the FINE differential voltage varies, the bias currents of the gain stage and latch are modified in a differential way. Although, the netto current flowing in the load is not changed, the negative resistance of the latch changes with the FINE tune current as:

$$- RTUNE = - \frac{2}{{g}_{m}} = - \frac{4 {V}_{T}}{{I}_{EE} + / - {I}_{FINE}} . \qquad ( 2 )$$

Wherein gₘ represents the small signal transconductance of the transistors in the corresponding stage,

V_{T} represents the thermal voltage

V_{T}=kT/q (k=Boltzmann's constant,

T=absolute temperature, q=electron charge),

I_{FINE} is the differential current comming from the fine tuning ports VFINE+ and VFINE−.

This provides a fine tuning mechanism with high linearity. The coarse-tuning has a larger gain constant and allows more than one octave COARSE tuning of the oscillation frequency.

In normal situations, temperature and process variations will make the swing at the output of the oscillator to vary. This is why, in order to keep the same voltage swing in a large tuning range, it has to make sure that the netto-current flowing in the load times the netto resistance present at the same node remains constant with respect to temperature and process variations. For keeping constant swing, the total bias current IEE must be able to be changed so as by COARSE tuning a charge in the netto resistance at the load to be compensated by the change in the bias current. This can be realized with a bias replica circuit as depicted in FIG. 7. The replica bias is a one to one copy of the bias condition in the gain stage. At VCOMMON, the common-mode voltage at the two outputs OUT+ and OUT− is sensed by using two resistors. The replica biasing tracks the temperature and process variations of the gain stage and latch circuit.

FIG. 8 shows the replica biasing together with common-mode control where a gain stage and its replica counterpart depicted.

The operational transconductance amplifier OTA (further shown in FIG. 8) due to its large gain copies the DC voltage VDC at the output node with an error given by the gain of the OTA. This voltage is denoted with VREPLICA in FIG. 8. This is possible because the OTA drives the base of the current-source transistors Q7, Q8 (for simplicity they have the same designation in FIG. 8 although not necessary in the real schematic). Since the same current flows in the gain-latch stage, due to the good matching among components, the same voltage VREPLICA will be copied at the output of the gain stage. When the coarse tuning voltage VCOARSE modifies the load resistor R of the gain-latch stage, the same thing happens in the replica-biasing circuit and the current IEE will be adjusted until the voltage at the output of the replica and gain circuit becomes VREPLICA≅VDC. This is equivalent of saying that the amplitude of oscillation remains constant independent of the tuning situation.

The advent of fiber optic communications has brought fully integrated optical receivers in which low-power becomes a must in order to cope with higher integration densities and the limited thermal capabilities of existing packages. At the receiver side, data and clock recovery units (DCR), usually PLL based, are needed to recover the clock information and to retime the incoming data.

FIG. 9 shows a preferred embodiment of a clock recovery circuit 120 which comprises a voltage controllable oscillator 122 of the kind as described above. The controllable oscillator 122 is part of a frequency locked loop further including a control signal generator 124. The controllable oscillator 122 has a coarse tuning port 122a which is coupled to the control signal generator 124 and corresponds to the coarse tuning control input 28 of FIG. 3 and to the coarse tuning ports VCOARSE+ and VCOARSE− of FIGS. 6 to 8. The control signal generator 124 receives a reference signal Sref from a reference signal generator 126, such as a crystal. The controllable oscillator 122 also forms part of a phase locked loop which comprises a phase detector 128 for generating a phase difference signal Sd which is indicative for a phase difference between an input signal Sin and a feedback signal Sb. The feedback signal Sb is obtained by a frequency divider 130 from the output signal of the controllable oscillator 122. Further, the clock recovery circuit 120 of FIG. 9 includes a charge pump 140 which receives the output signal from the phase detector 128 at its input and is connected with its output to a low-pass-filter 142 whose output is coupled to a fine tuning port 122b of the controllable oscillator 122. Which fine tuning port corresponds to the fine tuning control input 30 of FIG. 3 and to the fine tuning port VFINE+ and VFINE− of FIG. 6.

FIG. 10 shows a preferred embodiment of a receiver 150 for a fibre-optic channel 152. The receiver 150 comprises an input 156 for receiving an input signal Sin from a sensor 154 which is coupled to the fibre-optic channel 152. The receiver 150 of FIG. 10 further includes the clock recovery circuit 120 of FIG. 9 which is coupled to the input 156 for receiving the input signal Sin as reference signal. A data recovery circuit 158 is coupled to the clock recovery circuit 120 and to the input 156 comprises an output 160 which generates a digital output signal Sout in response to the input signal Sin.

FIG. 11 shows a further preferred embodiment of a data and clock recovery unit comprising a frequency locked loop and a phase locked loop. The data and clock recovery unit of FIG. 11 comprises matched voltage-controllable oscillators wherein the one controllable oscillator is part of the frequency loop and the other controllable oscillator is part of the phase locked loop. Further, the data and clock recovery unit of FIG. 11 comprises two charge pumps wherein the one charge pump CP1 is included in the frequency locked loop and the other charge pump CP2 is included in the phase locked loop. Moreover, the data and clock recovery unit of FIG. 11 comprises low-pass filters wherein the one low-pass filter LPF1 is included in the frequency locked loop and the other low-pass filter LPF2 is included in the phase locked loop.

1. Ring oscillator stage, comprising delay means (10; 32) having an input and an output,
further characterized by adjustable negative resistor means (−RTUNE) coupled to of said delay means (10; 32), in particular to the output of said delay means (10; 32).

2. Ring oscillator stage, in accordance with claim 1,
further characterized by current adjusting means for adjusting the current through said delay means.

3. Ring oscillator stage in accordance with claim 1 or 2,
further characterized by adjustable load means (R) connected to the output of said delay means (10; 32).

4. Ring oscillator stage in accordance with at least any one of claims 1 to 3, further comprising an output buffer means (12; 34) connected to the output of said delay means (10; 32).

5. Ring oscillator stage in accordance with claim 4, wherein said output buffer means (12; 34) includes a transistor (Q5; Q6), characterized in that said transistor (Q5; Q6) is also provided to be an element of said adjustable negative resistor (−RTUNE).

6. Ring oscillator stage in accordance with at least any one of claims 1 to 5, characterized in that said delay means (10; 32) consists of an inverter means.

7. Ring oscillator stage in accordance with at least any one of claims 1 to 6, provided as a differential ring oscillator stage (22),
characterized in that said delay means (32) consists of a gain amplifier means.

8. Ring oscillator stage in accordance with at least any one of claims 1 to 7, further characterized by a replica biasing means.

9. Ring oscillator comprising at least one ring oscillator stage in accordance with at least any one of the preceding claims.

10. Clock recovery circuit comprising an oscillator in accordance with claim 9.

11. Clock recovery circuit according to claim 10, comprising a controllable oscillator means which includes at least one oscillator in accordance with claim 9 and both is part of a frequency locked loop and a phase locked loop.

12. A receiver (150) for a fibre-optic channel (152) comprising
an input (156) for receiving an input signal (Sin) from a sensor (154) which is coupled to the fibre-optic channel (152),
a clock recovery circuit (120) according to claim 10 or 11 coupled to the input (156) for receiving said input signal (Sin) as a reference signal,
a data recovery circuit (158) coupled to said clock recovery circuit (120) and the input (156), for generating a digital output signal (Sout) in response to the input signal (Sin), and an output signal (CL) of the clock recovery circuit (120), and
an output (160) for providing the digital output signal (Sout).
